(19) United States
(12) Patent Application Publication
(10) Pub. No.: US 2007/0049009 A1
(43) Pub. Date: Mar. 1, 2007

(54) METHOD OF MANUFACTURING CONDUCTIVE LAYER

(76) Inventors: Chia-Lin Hsu, Tainan City (TW); Liang-Yuan Fang, Hsinchu County (TW); Shu-Jen Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,119

(22) Filed: Aug. 30, 2005

(51) Int. Cl. H01L 21/4763; H01L 21/44

(52) U.S. Cl. 438/629; 438/672

(57) ABSTRACT

A method of manufacturing a conductive layer is described. A substrate having a dielectric layer thereon is provided. The dielectric layer has a patterned structure and the patterned structure exposes a portion of the conductive layer. The surface of the substrate is cleaned in a first cleaning step and a cap layer is formed over the exposed portion of the conductive layer. Thereafter, the surface of the substrate is cleaned again in a second cleaning step to remove the residual cap layer on the surface of the dielectric layer. Finally, a dry cleaning step is performed to clean and dry the surface of the substrate.

### BACKGROUND OF THE INVENTION

1. Field of the Invention

The present invention relates to a method of manufacturing a semiconductor device. More particularly, the present invention relates to a method of manufacturing a conductive layer.

2. Description of the Related Art

The interconnection process in the fabrication of semiconductor devices is a special process for connecting various electronic components and circuits inside an ultra-large scale integrated (ULSI) circuit product. The interconnections are mainly constructed by conduction layers for conducting currents and by dielectric layers for isolating the conductive layers.

As the integrated circuit technology advances, in order to enhance the operating speed and functions, the integration of the integrated circuit devices must increase correspondingly. However, as the line width of the conductive lines decrease, the open circuit issue due to electro-migration may be more and more critical. In general, the electro-migration is problem caused since the electric conductivity of the conductive line is contributed by the free electrons of the conductive line such as the metal line. In the integrated circuits, the free electrons move along a specific path on the boundary of the metal grain of the narrow conductive line. Usually, after a certain period of time, the open circuit issue will be caused somewhere along the specific path in the conductive line. Accordingly, the open circuit issue may reduce the reliability of the integrated circuits drastically, or even make the integrated circuits fails.

Furthermore, in the process of forming a metallic conductive layer, a spin dry method is conventionally deployed to remove residuals such as residual metals or ions on the dielectric layer. However, the surface of a dielectric layer with a low dielectric constant or the surface of a chemical-mechanical polished (CMP) stop layer is usually hydrophobic. Hence, watermarks are usually generated during the spin dry process and lead to current leakage or short-circuit in the integrated circuits. In addition, the watermarks also increase the power consumption of the integrated circuits and generate undesired heat in the integrated circuits. Consequently, there is a need to provide a method of fabricating a conductive layer to prevent from the open circuit issue in the conductive layer and the generation of watermarks.

### SUMMARY OF THE INVENTION

Accordingly, the present invention is related to a method of manufacturing a conductive layer for eliminating the electro-migration issue due to narrowing of the line width and preventing the open circuit issue of the conductive line. Therefore, the reliability and the yield of the product are enhanced. In addition, the method of the present invention also comprises an isopropyl alcohol (IPA) dry-cleaning step to prevent the formation of watermarks. Therefore, the current leakage or short-circuit problem due to the conventional spin dry process may be avoided, and thus the performance and reliability of the product are improved.

According to one embodiment of the invention, a method of manufacturing a conductive layer comprising the following steps is provided. First, a substrate comprising a conductive layer therein is provided. In addition, a dielectric layer is formed on the surface of the substrate. The dielectric layer may comprise a patterned structure exposing a portion of the conductive layer. Next, the surface of the substrate is cleaned by a first cleaning step, and then a cap layer is formed over a surface of the exposed portion of the conductive layer. Thereafter, the surface of the substrate is cleaned by a second cleaning step, wherein a portion of the cap layer being residual on the surface of the dielectric layer may be removed. Finally, a dry cleaning step is performed to clean and dry the surface of the substrate.

In one embodiment of the present invention, after performing the first cleaning step and before forming the cap layer over the surface of the exposed portion of the conductive layer, further comprises activating the surface of the exposed portion of the conductive layer.

In one embodiment of the present invention, a material used for performing the first cleaning step comprises an organic acid or an inorganic acid.

In one embodiment of the present invention, a material of the cap layer comprises a metal or a metallic compound.

In one embodiment of the present invention, a material of the metal or metallic compound may comprise Co alloy or Ni alloy. The alloy element can be Mo, W, B, P, or their compound.

In one embodiment of the present invention, a material of the metallic compound comprises Co alloy or Ni alloy. The alloy element can be Mo, W, B, P, or their compound.

In one embodiment of the present invention, a material used for performing the second cleaning step comprises an organic acid or an inorganic compound.

In one embodiment of the present invention, the dry cleaning step comprises an isopropyl alcohol (IPA) dry-cleaning process. In addition, a material used for performing the isopropyl alcohol dry cleaning step comprises a mixture of isopropyl alcohol and nitrogen (N₂). In another embodiment of the present invention, the isopropyl alcohol dry cleaning step comprises a marangoni method or a rotagoni method.

Accordingly, in the present invention, a cap layer is formed over the surface of the conductive layer to prevent the open circuit issue due to the electro-migration, and thus the reliability of products may be enhanced. In addition, an isopropyl alcohol dry cleaning step is used to dry and clean the surface of the conductive layer, therefore, the generation of watermarks on the surface of the substrate can be avoided. As a result, the current leakage or short-circuit problem is reduced considerably and the performance of the products is improved significantly.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart showing the steps for manufacturing a conductive layer according to one embodiment of the present invention.

FIGS. 2A and 2B are schematic cross-sectional views of a semiconductor structure according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

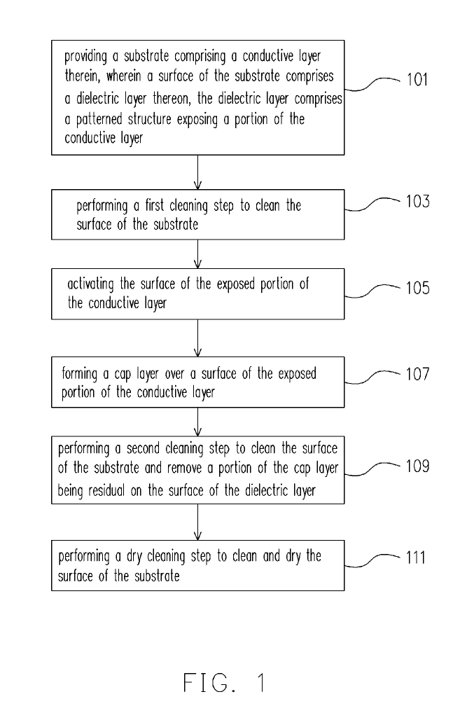

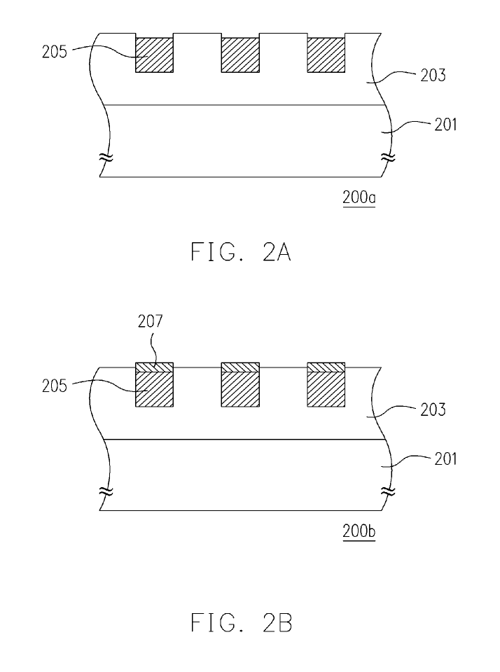

FIG. 1 is a flowchart showing the steps for fabricating a conductive layer according to one embodiment of the present invention. FIGS. 2A and 2B are schematic cross-sectional views of a semiconductor structure according to one embodiment of the present invention. As shown in FIG. 1 and the structural cross-section view after finishing the step 101 as shown in FIG. 2, a substrate 201 having a conductive layer 205 therein is provided in step 101. A dielectric layer 203 also covers the surface of the substrate 201. The dielectric layer 203 has a patterned structure exposing a portion of the conductive layer 205.

Thereafter, in step 103, a first cleaning step is performed to clean the surface of the substrate structure 200a. The first cleaning step is carried out using an organic or an inorganic acid, for example.

In step 107, a cap layer 207 may be formed over a surface of the exposed portion of the conductive layer 205. The structure after the completion of step 107 is shown in FIG. 2B. The material of the cap layer 207 may comprise a metal or a metallic compound. The metal or the metallic compound may comprises, for example, Co alloy or Ni alloy, in which the alloy element can be tungsten (W), phosphorus (P), boron (B), molybdenum (Mo) or a compound thereof. In another embodiment of the present invention, the metallic compound may comprise, for example, Co alloy or Ni alloy, in which the alloy element can be tungsten (W), phosphorus (P), boron (B), molybdenum (Mo) or a compound thereof, such as cobalt tungsten phosphide (CoWP) or cobalt tungsten boride (CoWB).

In one optional embodiment of the present invention, after performing the first cleaning step and before forming the cap layer 207 over the surface of the exposed portion of the conductive layer 205, further comprises the step 105 for activating the surface of the exposed portion of the conductive layer 205. In one embodiment of the present invention, the method of activating the surface of the exposed portion of the conductive layer 205 may comprise forming a Pd or Sn layer over the conductive layer 205.

Then, as shown in FIG. 2B, in step 109, a second cleaning step is performed to clean the surface of the substrate structure 200b, wherein a portion of the cap layer 207 being residual on the surface of the dielectric layer 203 may be removed. In one embodiment of the present invention, the second cleaning step is carried out using an organic or inorganic acid.

Thereafter, in step 111, a dry cleaning step is carried out to clean and dry the surface of the substrate structure 200b. The dry cleaning step includes performing an isopropyl alcohol (ISP) dry cleaning step. In one embodiment, the isopropyl alcohol (ISP) dry cleaning step may be carried out using a mixture of isopropyl alcohol and nitrogen (N₂), for example.

In one embodiment of the present invention, the isopropyl alcohol (ISP) dry cleaning step can be carried out using marangoni method. In the marangoni method, nitrogen is used as a carrier gas for spraying isopropyl alcohol containing vapor on the surface of the substrate structure 200b. At the same time, the substrate structure 200b immersed in a tank of de-ionized water is slowly withdrawn from the tank for cleaning and drying the surface of the substrate structure 200b.

In one embodiment of the present invention, the isopropyl alcohol (ISP) dry cleaning step may also be carried out using rotagoni method. In the rotagoni method, a rotator is used to spin the substrate structure 200b and, at the same time, a mixture of isopropyl alcohol and nitrogen is applied for cleaning and drying the surface of the substrate structure 200b.

Accordingly, in the present invention, a cap layer is formed over the surface of the conductive layer to prevent the open circuit issue due to electro-migration, therefore, the reliability of products is enhanced. In addition, an isopropyl alcohol dry cleaning step is used to dry and clean the surface of the conductive layer, so that the generation of watermarks on the surface of the substrate can be avoided. As a result, the current leakage or short-circuit problem is reduced and the performance of the products is improved. Moreover, the overall power consumption of the product may be reduced and the undesired heat may be significantly reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of manufacturing a conductive layer, comprising:
providing a substrate comprising a conductive layer therein, wherein a surface of the strate comprises a dielectric layer thereon, the dielectric layer comprises a patterned structure exposing a portion of the conductive layer;
performing a first cleaning step to clean the surface of the substrate;
forming a cap layer over a surface of the exposed portion of the conductive layer;
performing a second cleaning step to clean the surface of the substrate and remove a portion of the cap layer being residual on the surface of the dielectric layer;
performing a dry cleaning step to clean and dry the surface of the substrate.

2. The method of claim 1, wherein after performing the first cleaning step and before forming the cap layer over the surface of the exposed portion of the conductive layer, further comprises:
activating the surface of the exposed portion of the conductive layer.

3. The method of claim 1, wherein a material used for performing the first cleaning step comprises an organic acid.

4. The method of claim 1, wherein a material used for performing the first cleaning step comprises an inorganic acid.

5. The method of claim 1, wherein a material of the cap layer comprises a metal or a metallic compound.

6. The method of claim 5, wherein a material of the metal or the metallic compound comprises Co alloy or Ni alloy, wherein an alloy element comprises W, Mo, B, P, or a compound thereof.

7. The method of claim 5, wherein a material of the metallic compound comprises Co alloy or Ni alloy, wherein an alloy element comprises W, Mo, B, P, or a compound thereof.

8. The method of claim 1, wherein a material used for performing the second cleaning step comprises an organic acid.

9. The method of claim 1, wherein a material used for performing the second cleaning step comprises an inorganic acid.

10. The method of claim 1, wherein the dry cleaning step comprises an isopropyl alcohol dry cleaning step.

11. The method of claim 10, wherein a material used for performing the isopropyl alcohol dry cleaning step comprises a mixture of isopropyl alcohol and nitrogen (N₂).

12. The method of claim 11, wherein the isopropyl alcohol dry cleaning step comprises a marangoni method.

13. The method of claim 11, wherein the isopropyl alcohol dry cleaning step comprises a rotagoni method.
